(19) United States
(12) Patent Application Publication
(10) Pub. No.: US 2023/0309345 A1
(43) Pub. Date: Sep. 28, 2023

(54) DISPLAY DEVICE

(71) Applicant: Samsung Display Co., Ltd., Yongin-Si (KR)

(72) Inventors: Hae-Kwan Seo, Hwaseong-si (KR); Jinyoung Roh, Hwaseong-si (KR); Youngha Sohn, Seongnam-si (KR)

(21) Appl. No.: 18/124,615

(22) Filed: Mar. 22, 2023

(30) Foreign Application Priority Data
Mar. 22, 2022 (KR) 10-2022-0035437

(51) Int. Cl. H10K 59/121; H10K 59/122; H10K 59/131; H10K 59/35

(52) U.S. Cl. CPC H10K 59/1213; H10K 59/122; H10K 59/131; H10K 59/353

(57) ABSTRACT

A display device includes: a base substrate; a first pixel including: a first transistor disposed on the base substrate, a first conductive pattern disposed on the first transistor, a first light emitting element disposed on the first conductive pattern, and a first connection line connecting the first conductive pattern and the first light emitting element, and a second pixel adjacent to the first pixel in a first direction and including: a second transistor disposed on the base substrate, a second conductive pattern disposed on the second transistor, a second light emitting element disposed on the second conductive patten, and a second connection line connecting the second conductive pattern and the second light emitting element.

### CROSS-REFERENCE TO RELATED APPLICATION

This application claims priority from and the benefit of Korean Patent Application No. 10-2022-0035437 filed on Mar. 22, 2022, which is hereby incorporated by reference for all purposes as if fully set forth herein.

### BACKGROUND

### 1. Field

This disclosure pertains generally to a display device. More particularly, this disclosure relates to a display device that provides visual information.

### 2. Description of the Related Art

With the development of information technology, a display device, which is a connecting medium between a user and information, is increasing in importance. For example, the use of display devices such as liquid crystal display device (LCD), organic light emitting display device (OLED), plasma display device (PDP), quantum dot display device, or the like is increasing.

Meanwhile, the display device may include red sub-pixels, green sub-pixels, and blue sub-pixels to display an image. For example, the red sub-pixels, the green sub-pixels, and the blue sub-pixels may be arranged in the form of a stripe or a Pentile™ matrix.

### SUMMARY

This disclosure pertains to a display device capable of realizing high resolution.

A display device according to the present disclosure may include a base substrate, a first pixel including: a first transistor disposed on the base substrate, a first conductive pattern disposed on the first transistor, a first light emitting element disposed on the first conductive pattern, and a first connection line connecting the first conductive pattern and the first light emitting element, and a second pixel adjacent to the first pixel in a first direction and including: a second transistor disposed on the base substrate, a second conductive pattern disposed on the second transistor, a second light emitting element disposed on the second conductive patten, and a second connection line connecting the second conductive pattern and the second light emitting element.

Each of the first connection line and the second connection line may include a metal material.

The first light emitting element may include: a first pixel electrode, a first light emitting layer, and a first common electrode sequentially disposed on the base substrate. The second light emitting element may include: a second pixel electrode, a second light emitting layer, and a second common electrode sequentially disposed on the base substrate.

The first pixel electrode may include a first extension portion extending in the first direction, and the second pixel electrode may include a second extension portion extending in the first direction or in a direction opposite to the first direction.

The display device may further include a planarization layer covering the first connection line and the second connection line. The first extension portion of the first pixel electrode may be connected to the first connection line through a first contact hole formed by removing a portion of the planarization layer. The second extension portion of the second pixel electrode may be connected to the second connection line through a second contact hole formed by removing a portion of the planarization layer.

The display device may further include a pixel defining layer disposed on the base substrate and including a first opening aligned with a portion of the first pixel electrode and a second opening aligned with a portion of the second pixel electrode.

The first pixel and the second may be alternately arranged in an even-numbered row, and the first connection line may align with the second opening, and the second connection line may align with the first opening.

The first pixel and the second are alternately arranged in an odd-numbered row, and the first connection line may align with the first opening, and the second connection line may align with the second opening.

The first connection line may be spaced apart from the first opening and the second opening in a plan view. The second connection line may be spaced apart from the first opening and the second opening in the plan view.

The first connection line may have an “L” shape and the second connection line may have an “L” shape rotated by 90 degrees relative to the first connection line in a plan view.

The first connection line may extend in a same direction as the second connection line.

The display device may further include a third pixel adjacent to the first pixel and the second pixel in a second orthogonal to the first direction and including a third transistor, a third conductive pattern, and a third light emitting element sequentially disposed on the base substrate.

The third pixel may be repeatedly arranged in each of a first sub-row of a first row and a first sub-row of a second row. The first pixel and the second pixel may be alternately arranged in each of a second sub-row of the first row and a second sub-row of the second row.

The first pixel may be a red sub-pixel, the second pixel may be a blue sub-pixel, and the third pixel may be a green sub-pixel.

The display device may further include a first data line connected to the first pixel and configured to provide a red data signal to the first pixel, and a second data line connected to the second pixel and configured to provide a blue data signal to the second pixel.

A display device according to the present disclosure may include a base substrate, a transistor disposed on the base substrate, a conductive pattern disposed on the transistor and connected to the transistor, a light emitting element including a pixel electrode, a light emitting layer, and a common electrode sequentially disposed on the conductive pattern, a pixel defining layer disposed on the conductive pattern and including an opening aligned with a portion of the pixel electrode, and a connection line disposed between the conductive patten and the pixel electrode.

The connection line may align with the opening.

The connection line may be spaced apart from the opening in a plan view.

The connection line may have an “L” shape in a plan view.

The light emitting element may emit red light or blue light.

A display device according to the present disclosure may include a base substrate, a first pixel (e.g., a red sub-pixel), and a second pixel (e.g., a blue sub-pixel) adjacent to the first pixel. Each of the first pixel and the second pixel may include a transistor, a conductive patten disposed on the transistor, a light emitting element disposed on the conductive patten, and a connection line connecting the conductive pattern and the light emitting element.

Accordingly, power consumption of the display device may be reduced.

### BRIEF DESCRIPTION OF THE DRAWINGS

Illustrative, non-limiting embodiments will be more clearly understood from the following detailed description in conjunction with the accompanying drawings.

FIGS. 1 and 2 are plan views illustrating a display device according to an embodiment.

FIG. 3 is a plan view illustrating an enlarged area “A” of FIG. 1.

FIG. 4 is a cross-sectional view taken along line I-I′ of FIG. 3.

FIG. 5 is a cross-sectional view taken along line II-IT of FIG. 3.

FIG. 6 is a cross-sectional view taken along line III-III′ of FIG. 3.

FIG. 7 is a cross-sectional view taken along line IV-IV′ of FIG. 3.

FIGS. 8, 9, and 10 are plan views illustrating an enlarged portion of a display area of a display device according to another embodiment.

FIG. 11 is a plan view illustrating pixels and data lines of a display device according to still another embodiment.

FIG. 12 is a plan view illustrating an enlarged portion of a display area of a display device according to still another embodiment.

### DETAILED DESCRIPTION OF THE EMBODIMENTS

Hereinafter, embodiments of the present disclosure will be explained in detail with reference to the accompanying drawings. The same reference numerals are used for the same components in the drawings, and redundant descriptions of the same components will be omitted.

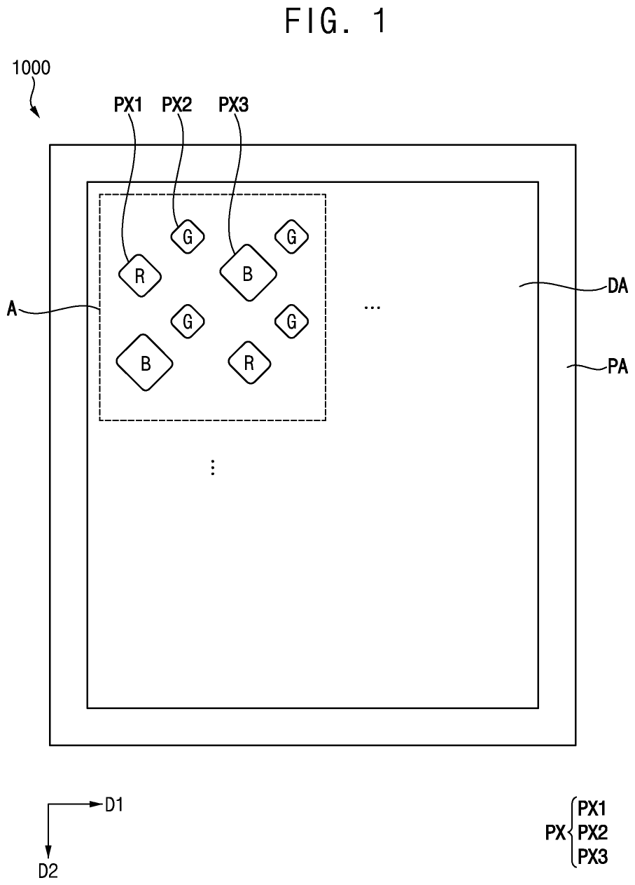

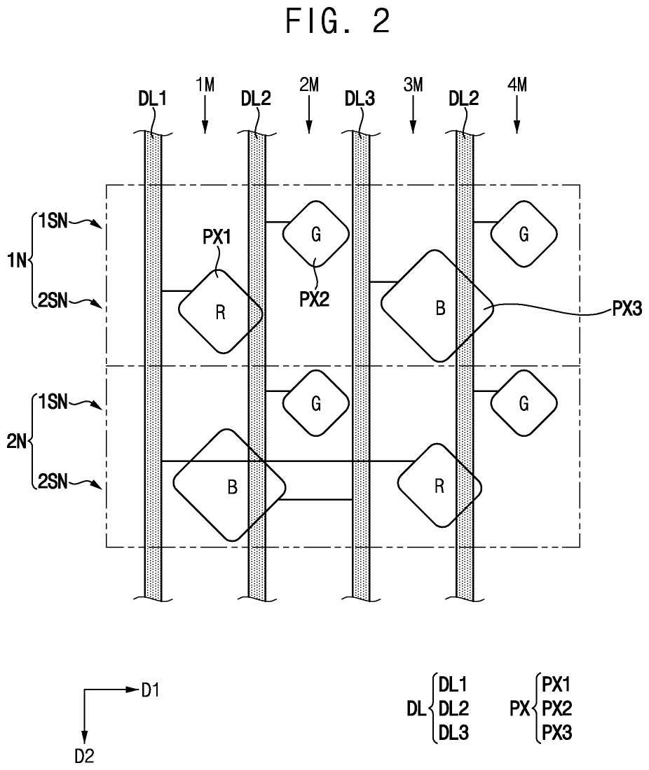

FIGS. 1 and 2 are plan views illustrating a display device according to an embodiment. For example, FIG. 2 is a plan view illustrating a plurality of pixels PX and a plurality of data lines DL of the display device 1000.

Referring to FIGS. 1 and 2, the display device 1000 according to an embodiment may include a display area DA and a peripheral area PA. The display area DA may be an area capable of displaying an image by generating light or adjusting transmittance of light provided from an external light source. The peripheral area PA may be an area that does not display an image. The peripheral area PA may be located around the display area DA. For example, the peripheral area PA may surround the display area DA.

The display device 1000 may include the plurality of pixels PX arranged in the display area DA. Each of the pixels PX may include a first pixel PX1, a second pixel PX2, and a third pixel PX3. For example, the first pixel PX1 may be a red sub-pixel R emitting red light, the second pixel PX2 may be a green sub-pixel (G) emitting green light, and the third pixel PX3 may be a blue sub-pixel (B) emitting blue light. That is, one pixel PX may display one predetermined basic color. In other words, one pixel PX may be a minimum unit capable of displaying colors independent of other pixels PX. In the claims, the second pixel PX2 may be the blue sub-pixel (B) and the third pixel PX3 may be the green sub-pixel (G).

In a plan view, the first, second, and third pixels PX1, PX2, and PX3 may be repeatedly arranged in a first direction D1 and a second direction D2 orthogonal to the first direction D1. In an embodiment, the first, second, and third pixels PX1, PX2, and PX3 may be arranged in a Pentile™ matrix. Each of the first, second, and third pixels PX1, PX2, and PX3 may apply a rendering operation that expresses a color by sharing a light emitting of an adjacent pixel. However, the present invention is not limited thereto, and the first, second, and third pixels PX1, PX2, and PX3 may be arranged in various forms such as a stripe arrangement, a mosaic arrangement, and the like.

FIG. 2 depicts the area A arranged into rows (1N, 2N, etc.) and columns (1M, 2M, etc.). The rows may include two sub-rows (SN). For example, the second pixels PX2 may be repeatedly arranged along the first direction D1 in a first sub-row 1SN of a first row 1N. The first pixel PX1 and the third pixel PX3 may be alternately arranged along the first direction D1 in a second sub-row 2SN of the first row 1N adjacent to the firs sub-row 1SN of the first row 1N. Similarly, the second pixels PX2 may be repeatedly arranged along the first direction D1 in first sub-row 1SN of a second row 2N. The first pixel PX1 and the third pixel PX3 may be alternately arranged along the first direction D1 in a second sub-row 2SN of the second row 2N adjacent to the firs sub-row 1SN of the second row 2N. Such pixel arrangement may be repeated up to a predetermined row.

The rows 1N, 2N, etc. may be divided into mutually exclusive rectangular areas, as depicted in FIG. 2 by the broken lines. In contrast, the sub-rows are not necessarily divisible into mutually exclusive areas with straight lines. For example, in the first row 1N, the second pixel PX2 arranged in the first sub-row 1SN may face in a first diagonal direction (e.g., a direction between a direction opposite to the first direction D1 and the second direction D2) the first pixel PX1 arranged in the second sub-row 2SN, and may face in a second diagonal direction (e.g., a direction between the first direction D1 and the second direction D2) the third pixel PX3 arranged in the second sub-row 2SN. Similarly, in the second row 2N, the second pixel PX2 arranged in the first sub-row 1SN may face in the second diagonal direction the first pixel PX1 arranged in the sub-row 2SN, and may face in the first diagonal the third pixel PX3 arranged in the sub-row 2SN.

Accordingly, the first pixels PX1 and the third pixels PX3 may be alternately arranged along the second direction D2 orthogonal to the first direction D1 in a first column 1M, and the second pixels PX2 may be repeatedly arranged in the second direction D2 in a second column 2M adjacent the first column 1M. In addition, the third pixel PX3 and the first pixel PX1 may be alternately arranged along the second direction in a third column 3M adjacent the second column 2M, and the second PX2 may be repeatedly arranged in the second direction D2 in a fourth column 4M adjacent to the third column 3M. Such pixel arrangement may be repeated up to a predetermined column.

Each of the first, second, and third pixels PX1, PX2, and PX3 may have a polygonal shape. In an embodiment, each of the first, second, and third pixels PX1, PX2, and PX3 may have a rhombus shape in a plan view. However, the configuration of the present invention is not limited thereto, and each of the first, second, and third pixels PX1, PX2, and PX3 may have a triangular shape, a rectangular shape, a hexagonal shape, a circular shape, an elliptical shape, or the like.

The first, second, and third pixels PX1, PX2, and PX3 may be different from each other. In an embodiment, the area of the first pixel PX1 may be smaller than the area of the third pixel PX3. In this case, the area of the second pixel PX2 may be smaller than the area of the first pixel PX1. That is, the third pixel PX3 may have the largest area and the second pixel PX2 may have the smallest area. However, the configuration of the present invention is not limited thereto.

Each of the pixels PX may include a transistor, a conductive pattern, a light emitting element, and the like. A detailed description of the configuration of each of the pixels PX will be described later.

A signal line providing a driving signal to the pixels PX, a power line providing power to the pixels PX, and the like may be disposed in the display area DA. For example, the data lines DL providing data signals to the pixels PX may be disposed in the display area DA.

The data lines DL may include first data lines DL1, second data lines DL2, and third data lines DL3. In an embodiment, each of the first pixels PX1 may be connected to a first data line DL1, which may provide a data signal of a first color (e.g., red) to the first pixels PX1. Each of the second pixels PX2 may be connected to a second data line DL2, which may provide a data signal of a second color (e.g., green) to the second pixels PX2. Each of the third pixels PX3 may be connected to a third data line DL3, which may provide a data signal of a third color (e.g., blue) to the third pixels PX3. That is, each of the first, second, and third data lines DL1, DL2, and DL3 may provide a data signal of a single color to each pixel PX1, PX2, and PX3, respectively.

In one embodiment, the first data line DL1 adjacent to the first column 1M may be connected to the first pixel PX1 arranged in the second sub-row 2SN of the first row 1N and the first column 1M and the first data line DL1 may be connected to the first pixel PX1 arranged in the second sub-row 2SN of the second row 2N and the third column 3M. The second data line DL2 adjacent to the second column 2M may connected to the second pixel PX2 arranged in the first sub-rows 1SN of the first row 1N and the second row 2N. The third data line DL3 may be connected to the third pixel PX3 in the first row 1N and third column 3M, and to the third pixel PX3 in the second row 2N and the first column 1M.

Each of the first, second, and third data lines DL1, DL2, and DL3 may extend in a second direction D2 orthogonal to the first direction D1. In addition, each of the first, second, and third data lines DL1, DL2, and DL3 may be disposed to be spaced apart from each other in the first direction D1. For example, the first data line DL1 and the third data line DL3 may be alternately disposed in the first direction D1 with the second data line DL2 interposed therebetween. In the embodiment of FIG. 2, every other data line is a second data line DL2, and the data line between two adjacent data lines DL2 alternates between the first data line DL1 and the third data line DL3.

However, although an organic light emitting display device (OLED) is described for the display device 1000 of the present invention, the configuration of the present disclosure is not limited thereto. In other embodiments, the display device 1000 may include a liquid crystal display device (LCD), a field emission display device (FED), a plasma display device (PDP), an electrophoretic display device (EPD), an inorganic light emitting display device (ILED), or a quantum dot display device.

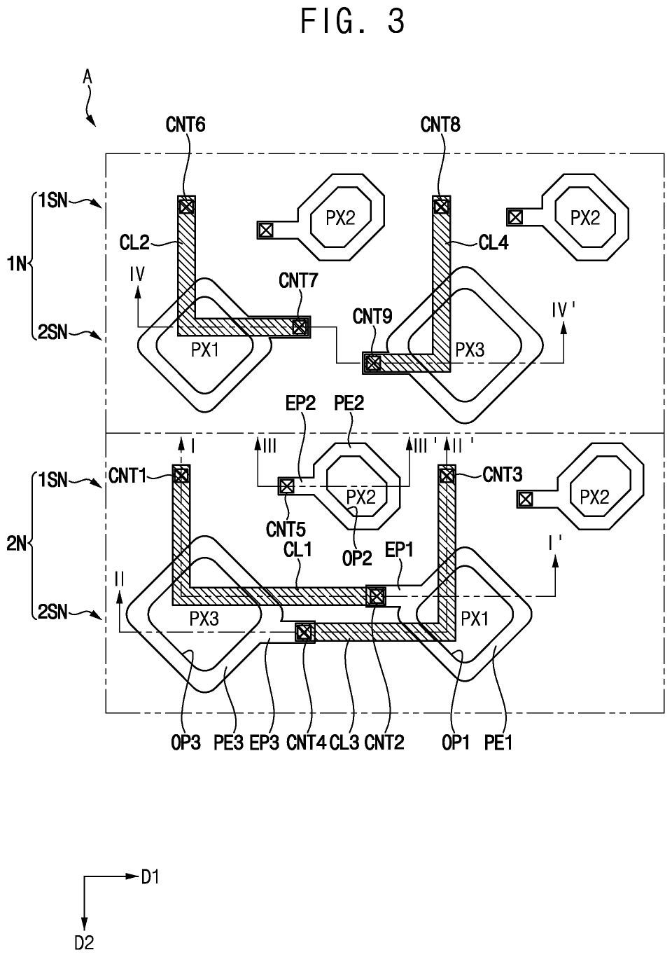

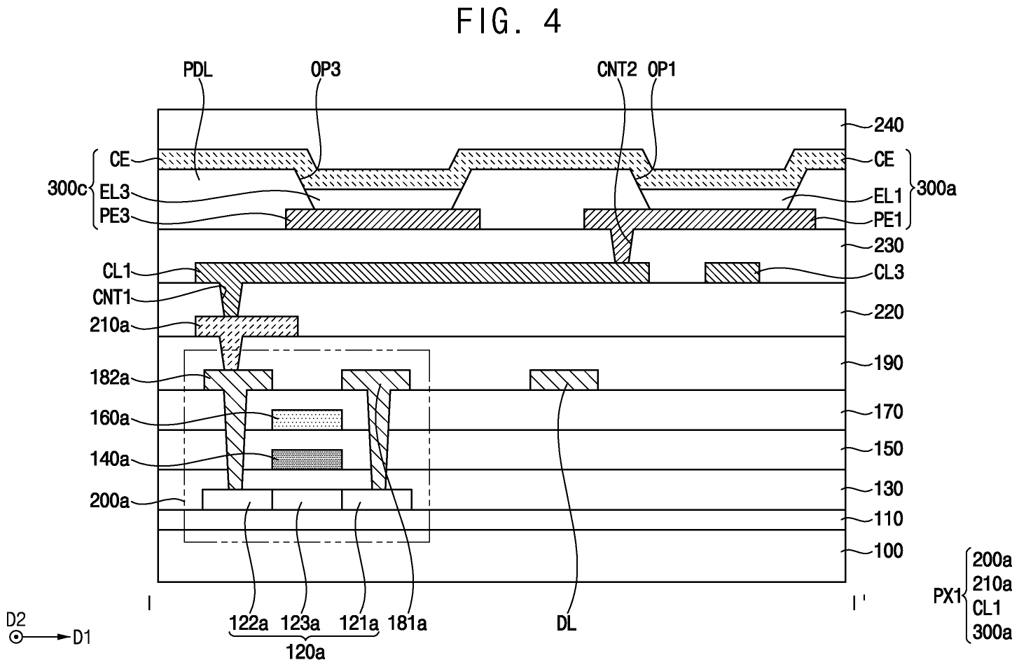

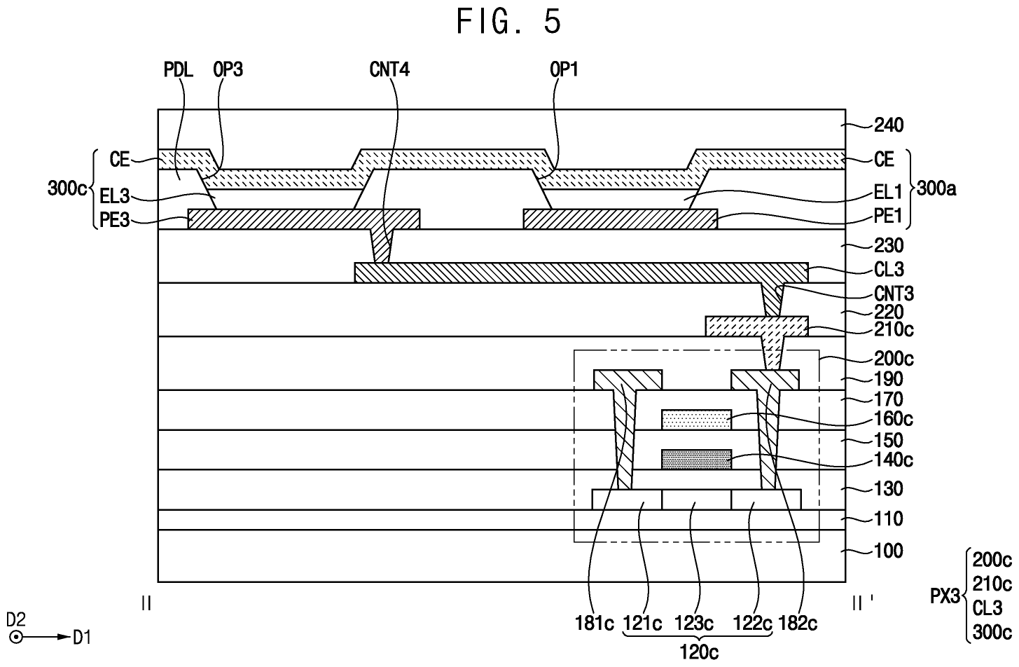

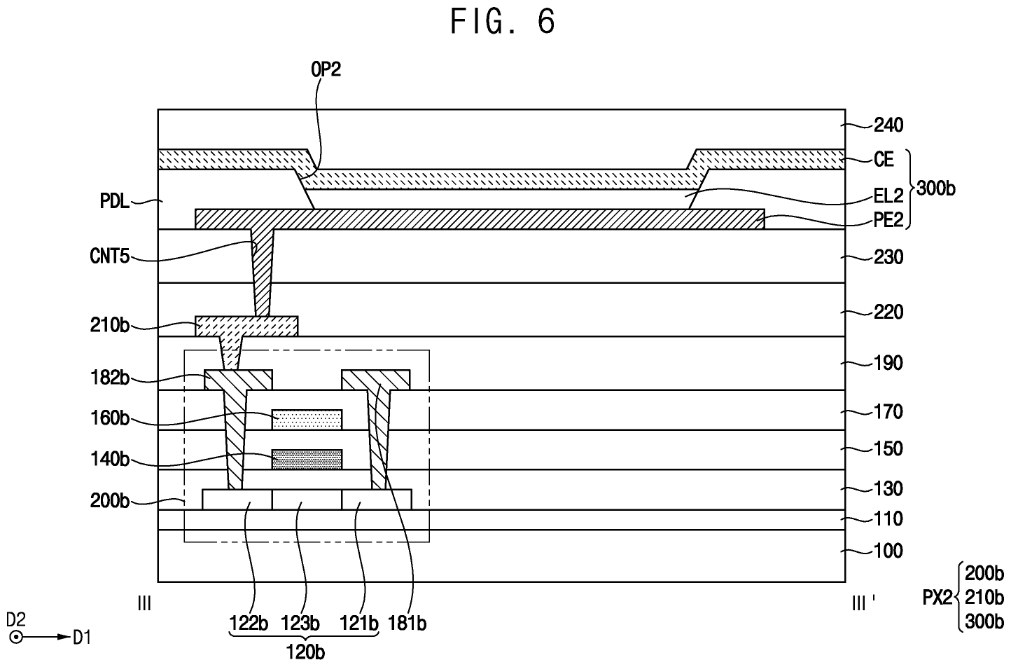

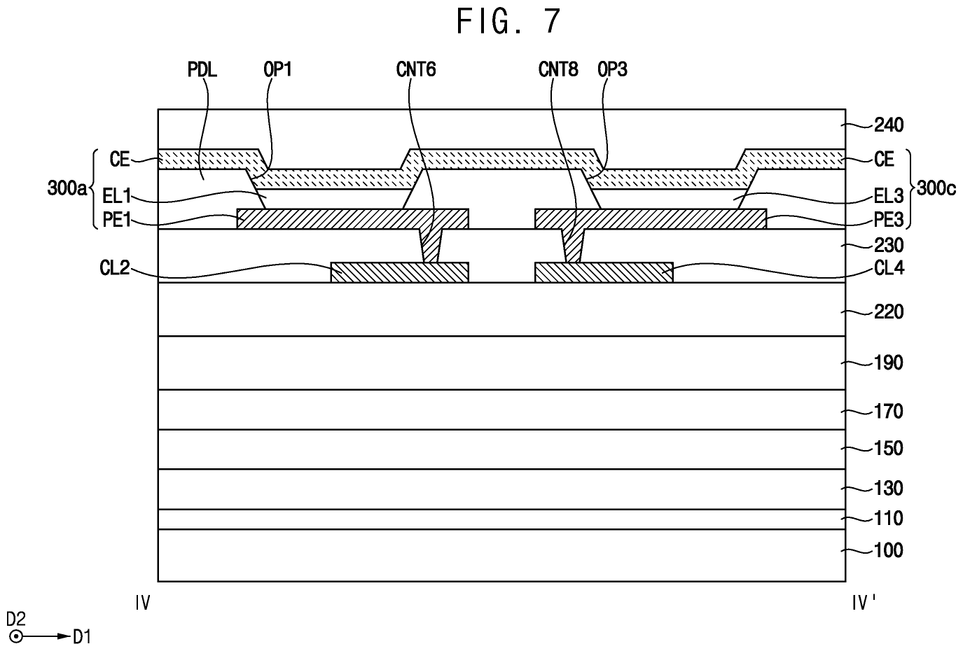

FIG. 3 is a plan view illustrating an enlarged area “A” of FIG. 1. FIG. 4 is a cross-sectional view taken along line I-I′ of FIG. 3. FIG. 5 is a cross-sectional view taken along line II-IT of FIG. 3. FIG. 6 is a cross-sectional view taken along line III-III′ of FIG. 3. FIG. 7 is a cross-sectional view taken along line IV-IV′ of FIG. 3. For example, FIG. 3 is a plan view of an enlarged portion of the display area DA of the display device 1000 of FIG. 1.

Referring to FIG. 3, the display device 1000 according to an embodiment of the present disclosure may include first, second, and third pixels PX1, PX2, and PX3 that are repeatedly arranged in the first direction D1 and the second direction D2 orthogonal to the first direction D1 in the display area DA. That is, the first, second, and third pixels PX1, PX2, and PX3 may be repeatedly arranged such that odd-numbered rows resemble the first row 1N and even-numbered rows resemble the second row 2N.

The first pixel PX1 may include a first transistor 200a, a first conductive pattern 210a, a first connection line CL1 (or a second connection line CL2), and a first light emitting element 300a. The second pixel PX2 may include a second transistor 200b, a second conductive pattern 210b, and a second light emitting element 300b. The third pixel PX3 may include a third transistor 200c, a third conductive pattern 210c, a third connection line CL3 (or a fourth connection line CL4), and a third light emitting element 300c.

The first pixel PX1 and the third pixel PX3 positioned in the even-numbered row may include the first connection line CL1 and the third connection line CL3, respectively. The first pixel PX1 and the third pixel PX3 positioned in the odd-numbered row may include the second connection line CL2 and the fourth connection line CL4, respectively.

The first connection line CL1 may be connected to the first conductive pattern 210a through a first contact hole CNT1. The third connection line CL3 may be connected to the third conductive pattern 210c through a third contact hole CNT3. Similarly, the second connection line CL2 may be connected to a first conductive pattern through a sixth contact hole CNT6, and the fourth connection line CL4 may be connected to a third conductive pattern through a eighth contact hole CNT8. The first conductive pattern and the third conductive pattern may be disposed on the same layer as the conductive patterns 210a, 210b, and 210c (e.g., a first planarization layer 190 of FIG. 4).

As depicted in FIG. 3, the first pixel electrode PE1 may include a first extension portion EP1, the second pixel electrode PE1 may include a second extension portion EP2, and the third pixel electrode PE3 may include a third extension portion EP3.

In an embodiment, when the pixels PX1, PX2, and PX3 are arranged in the even-numbered row (e.g., the second row 2N), the first extension portion EP1 may protrude in a direction opposite to the first direction D1 in a plan view, the second extension portion EP2 may protrude in a direction opposite to the first direction D1 in a plan view, and the third extension portion EP3 may protrude in the first direction D1 in a plan view. That is, the first extension portion EP1 may protrude in the same direction as the second extension portion EP2.

In an embodiment, when the pixels PX1, PX2, and PX3 are arranged in the odd-numbered row (e.g., the first row 1N), the first extension portion EP1 may extend in the first direction D1 in a plan view, the second extension portion EP2 may extend in a direction opposite to the first direction D1 in a plan view, and the third extension portion EP3 may extend in a direction opposite to the first direction D1 in a plan view. That is, the second extension portion EP2 may extend in the same direction as the third extension portion EP3.

For example, the third extension portion EP3 located in the second sub-row 2SN of the second row 2N may be located farther along in the second direction D2 than the first extension portion EP1 located in the second sub-row 2SN of the second row 2N in a plan view. In addition, the third extension portion EP3 located in the second sub-row 2SN of the first row 1N may be located farther along in the second direction D2 than the first extension portion EP1 located in the second sub-row 2SN of the first row 1N.

In the first, second, and third pixel electrodes PE1, PE2, and PE3 located in the even-numbered row (e.g., the second row 2N), the first pixel electrodes PE1 may be connected to the first connection line CL1 through a second contact hole CNT2, the second pixel electrode PE2 may be connected to the second conductive pattern 210b through a fifth contact hole CNT5, and the third pixel electrode PE3 may be connected to the third connection line CL3 through a fourth contact hole CNT4. Similarly, in the first, second, and third pixel electrodes PE1, PE2, and PE3 located in the odd-numbered row (e.g., the first row 1N), the first pixel electrode PE1 may be connected to the second connection line CL2 through a seven hole CNT7 and the third pixel electrode PE3 may be connected to the fourth connection line CL4 through the ninth contact hole CNT9.

In an embodiment, the first connection line CL1 may align with a third opening OP3 that in turn aligns with a portion of the third pixel electrode PE3 of a pixel defining layer (e.g., a pixel defining layer PDL of FIG. 4), and the third connection line CL3 may align with a first opening OP1 that in turn aligns with a portion of the first pixel electrode PE1 of the pixel defining layer PDL. As used herein, A “aligns with” B indicates that a straight, imaginary line in a direction that is orthogonal to both the first direction D1 and the second direction D2 crosses both A and B. In plan view, the first connection line CL1 may be spaced apart from the first opening OP1, and the third connection line CL3 may be spaced apart from the third opening OP3. In other words, the first connection line CL1 may not align with the first opening OP1, and the third connection line CL3 may not align with the third opening OP3.

In an embodiment, the second connection line CL2 may align with the first opening OP1 of the pixel defining layer PDL, and the fourth connection line CL4 may align with the third opening OP3 of the pixel defining layer PDL. That is, the second connection line CL2 may be spaced apart from the third opening OP3 in a plan view, and the fourth connection line CL4 may be spaced apart from the first opening OP1 in a plan view. In other words, the second connection line CL2 may not align with the third opening OP3, and the fourth connection line CL4 may not align with the first opening OP1.

In a plan view, the first connection line CL1 may have an “L” shape, and the third connection line CL3 may have an “L” shape rotated by 90 degrees with respect to the first connection line CL1. Similarly, in a plan view, the second connection line CL2 may have an “L” shape, and the fourth connection line CL4 may have an “L” shape rotated by 90 degrees with respect to the second connection line CL2. However, the configuration of the present disclosure is not limited thereto, and each of the first, second, third, and fourth connecting lines CL1, CL2, CL3 and CL4 may have various shapes in a plan view.

Hereinafter, a configuration included in the display device 1000 according to an embodiment of the present disclosure will be described in more detail according to a stacked structure.

Referring to FIGS. 3, 4, 5, 6, and 7, the display device 1000 according to an embodiment may include a base substrate 100, a buffer layer 110, the first, second, and third pixels. PX1, PX2, and PX3, first and second gate insulating layers 130 and 150, an interlayer insulating layer 170, first, second, and third planarization layers 190, 220, and 230, and a pixel defining layer PDL and an encapsulation layer 240.

As described above, the first pixel PX1 may include the first transistor 200a, the first conductive pattern 210a, the first connection line CL1 (or the second connection line CL2), and the first light emitting element 300. The second pixel PX2 may include the second transistor 200b, the second conductive pattern 210b, and the second light emitting element 300b. The third pixel PX3 may include the third transistor 200c, the third conductive pattern 210c, the third connection line CL3 (or the fourth connection line CL4), and the third light emitting element 300c.

The first transistor 200a may include a first active layer 120a, a first lower gate electrode 140a, a first upper gate electrode 160a, a first source electrode 181a, and a second drain electrode 182b. The second transistor 200b may include a second active layer 120b, a second lower gate electrode 140b, a second upper gate electrode 160b, a second source electrode 181b, and a second drain electrode 182b. The third transistor 200c may include a third active layer 120c, a third lower gate electrode 140c, a third upper gate electrode 160c, a third source electrode 181c, and a third drain electrode 182c.

The first light emitting element 300a may include the first pixel electrode PE1, a first light emitting layer EL1, and a common electrode CE. The second light emitting element 300b may include the second pixel electrode PE2, a second light emitting layer EL2, and the common electrode CE, and the third light emitting element 300c may include the third pixel electrode PE3, a third emission layer EL3, and the common electrode CE.

The base substrate 100 may include a transparent or opaque material. The base substrate 100 may be formed of a transparent resin substrate. An example of the transparent resin substrate that can be used as the base substrate 100 may be a polyimide substrate. In this case, the polyimide substrate may include a first polyimide layer, a barrier film layer, a second polyimide layer, and the like. Alternatively, the base substrate 100 may include a quartz substrate, a synthetic quartz substrate, a calcium fluoride substrate, a fluorine-doped quartz substrate, a soda-lime glass substrate, a non-alkali glass substrate, and the like. These may be used alone or in combination with each other.

The buffer layer 110 may be disposed on the base substrate 100. The buffer layer 110 may prevent diffusion of metal atoms or impurities from the base substrate 100 to the first, second, and third transistor 200a, 200b, and 200c. In addition, when the surface of the base substrate 100 is not uniform, the buffer layer 110 may improve the flatness of the surface of the base substrate 100. For example, the buffer layer 110 may include an organic material or an inorganic material.

The active layers 120a, 120b, and 120c may be disposed on the buffer layer 110. The active layers 120a, 120b, and 120c may include a metal oxide semiconductor, an inorganic semiconductor (e.g., amorphous silicon, polysilicon), or an organic semiconductor. The active layers 120a, 120b, and 120c may include source regions 121a, 121b, and 121c, drain regions 122a, 122b, and 122c, and channel regions 123a, 123b, and 123c located between the source regions 121a, 121b, and 121c and the drain regions 122a, 122b, and 122c, respectively.

The first gate insulating layer 130 may be disposed on the buffer layer 110. The first gate insulating layer 130 may sufficiently cover the active layers 120a, 120b, and 120c, and may have a substantially flat upper surface without creating a step around the active layers 120a, 120b, and 120c. Alternatively, the first gate insulating layer 130 may cover the active layers 120a, 120b, and 120c, and may be disposed along the profile of the active layers 120a, 120b, and 120c to have a uniform thickness. For example, the first gate insulating layer 130 may include a silicon compound such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These may be used alone or in combination with each other.

The lower gate electrodes 140a, 140b, and 140c may be disposed on the first gate insulating layer 130. The lower gate electrodes 140a, 140b, and 140c may overlap the channel regions 123a, 123b, and 123c of the active layers 120a, 120b, and 120c, respectively. For example, the lower gate electrodes 140a, 140b, and 140c may include a metal, an alloy, a metal nitride, a conductive metal oxide, a transparent conductive material, and the like. These may be used alone or in combination with each other. Alternatively, the lower gate electrodes 140a, 140b, and 140c may have a multilayer structure including a plurality of metal layers. For example, the metal layers may have different thicknesses or may include different materials.

The second gate insulating layer 150 may be disposed on the first gate insulating layer 130. The second gate insulating layer 150 may sufficiently cover the lower gate electrodes 140a, 140b, and 140c, and may have a substantially flat upper surface without creating a step around the lower gate electrodes 140a, 140b, and 140c. Alternatively, the second gate insulating layer 150 may cover the lower gate electrodes 140a, 140b, and 140c, and may be disposed along the profile of the lower gate electrodes 140a, 140b, and 140c to have a uniform thickness. For example, the second gate insulating layer 150 may include a silicon compound such as silicon oxide, silicon nitride, silicon oxynitride, and the like. These may be used alone or in combination with each other.

The upper gate electrodes 160a, 160b, and 160c may be disposed on the second gate insulating layer 150. The upper gate electrodes 160a, 160b, and 160c may overlap the channel regions 123a, 123b, and 123c of the active layers 120a, 120b, and 120c, respectively. For example, the upper gate electrodes 160a, 160b, and 160c may include a metal, an alloy, a metal nitride, a conductive metal oxide, a transparent conductive material, and the like. These may be used alone or in combination with each other. Alternatively, the upper gate electrodes 160a, 160b, and 160c may have a multilayer structure including a plurality of metal layers. For example, the metal layers may have different thicknesses or may include different materials.

For example, the lower gate electrodes 140a, 140b, and 140c and the upper gate electrodes 160a, 160b, and 160c may function as a storage capacitor, respectively.

The interlayer insulating layer 170 may be disposed on the second gate insulating layer 150. The interlayer insulating layer 170 may sufficiently cover the upper gate electrodes 160a, 160b, and 160c. For example, the interlayer insulating layer 170 may include a silicon compound such as silicon oxide, silicon nitride, silicon oxynitride, and the like. These may be used alone or in combination with each other.

The source electrodes 181a, 181b, and 181c and the drain electrodes 182a, 182b, and 182c may be disposed on the interlayer insulating layer 170. The source electrodes 181a, 181b, and 181c may be connected to the source regions 121a, 121b, and 121c of the active layers 120a, 120b, and 120c through a contact hole formed by removing a first portion of the first gate insulating layer 130, the second gate insulating layer 150, and the interlayer insulating layer 170, respectively. The drain electrodes 182a, 182b, and 182c may be connected to the drain regions 123a, 123b, and 123c of the active layers 120a, 120b, and 120c through a contact hole formed by removing a second portion of the first gate insulating layer 130, the second gate insulating layer 150, and the interlayer insulating layer 170, respectively.

For example, each of the source electrodes 181a, 181b, and 181c and the drain electrodes 182a, 182b, and 182c may include a metal, an alloy, a metal nitride, a conductive metal oxide, a transparent conductive material, and the like. These may be used alone or in combination with each other. Alternatively, each of the source electrodes 181a, 181b, and 181c and the drain electrodes 182a, 182b, and 182c may have a multi-layered structure including a plurality of metal layers. For example, the metal layers may have different thicknesses or may include different materials.

Accordingly, the transistors 200a, 200b, and 200c each including the active layers 120a, 120b, and 120c, the lower gate electrodes 140a, 140b, and 140c, the upper gate electrodes 160a, 160b, and 160c, the source electrodes 181a, 181b, and 181c, and the drain electrode 182a, 182b and 182c may be disposed on the base substrate 100.

A data line (e.g., the data line DL of FIG. 2) may be disposed on the interlayer insulating layer 170. In an embodiment, the data line DL may be disposed on the same layer as the source electrodes 181a, 181b, and 181c and the drain electrodes 182a, 182b, and 182c. That is, the data line DL may include the same material as the source electrodes 181a, 181b, and 181c and the drain electrodes 182a, 182b, and 182c.

The first planarization layer 190 may be disposed on the interlayer insulating layer 170. The first planarization layer 190 may sufficiently cover the source electrodes 181a, 181b, and 181c, the drain electrodes 182a, 182b, and 182c, and the data line DL. The first planarization layer 190 may include an organic material or an inorganic material. For example, the first planarization layer 190 may include an organic material such as a polyimide-based resin, a photoresist, a polyacryl-based resin, a polyimide-based resin, a siloxane-based resin, and the like. These may be used alone or in combination.

The conductive patterns 210a, 210b, and 210c may be disposed on the first planarization layer 190. The conductive patterns 210a, 210b, and 210c may be connected to the drain electrodes 182a, 182b, and 182c through a contact hole formed by removing a portion of the first planarization layer 190, respectively. For example, the conductive patterns 210a, 210b, and 210c may include a metal, an alloy, a metal nitride, a conductive metal oxide, a transparent conductive material, and the like. These may be used alone or in combination with each other.

The second planarization layer 220 may be disposed on the first planarization layer 190. The second planarization layer 220 may sufficiently cover the conductive patterns 210a, 210b, and 210c. The second planarization layer 220 may include an organic material or an inorganic material. For example, the second planarization layer 220 may include an organic material such as a polyimide-based resin, a photoresist, a polyacrylic resin, a polyamide-based resin, a siloxane-based resin, and the like. These may be used alone or in combination.

In an embodiment, the first, second, third, and fourth connection lines CL1, CL2, CL3, and CL4 may be disposed on the second planarization layer 220. The first connection line CL1 may be connected to the first conductive pattern 210a through the first contact hole CNT1 formed by removing a portion of the second planarization layer 220. The third connection line CL3 may be connected to the third conductive pattern 210c through the third contact hole CNT3 formed by removing a portion of the second planarization layer 220.

For example, each of the first, second, third, and fourth connection lines CL1, CL2, CL3, and CL4 may include a metal, an alloy, a metal nitride, a conductive metal oxide, a transparent conductive material, and the like. These may be used alone or in combination.

The third planarization layer 230 may be disposed on the second planarization layer 220. The third planarization layer 230 may sufficiently cover the first, second, third, and fourth connection lines CL1, CL2, CL3, and CL4. The third planarization layer 230 may include an organic material or an inorganic material. For example, the third planarization layer 230 may include an organic material such as a polyimide-based resin, a photoresist, a polyacrylic resin, a polyamide-based resin, a siloxane-based resin, and the like. These may be used alone or in combination with each other.

The pixel electrodes PE1, PE2, and PE3 may be disposed on the third planarization layer 230. The first pixel electrode PE1 may include the first extension portion EP1, the second pixel electrode PE1 may include the second extension portion EP2, and the third pixel electrode PE3 may include the third extension portion EP3.

The first extension portion EP1 of the first pixel electrode PE1 may be connected to the first connection line CL1 through the second contact hole CNT2 formed by removing a portion of the third planarization layer 230. The second extension portion EP2 of the second pixel electrode PE2 may be connected to the second conductive pattern 210b through the fifth contact hole CNT 5 formed by removing a portion of the second planarization layer 210 and the third planarization layer 230. The third extension portion EP3 of the third pixel electrode PE3 may be connected to the third connection line CL3 through the fourth contact hole CNT4 formed by removing a portion of the third planarization layer 220.

For example, the pixel electrodes PE1, PE2, and PE3 may include a metal, an alloy, a metal nitride, a conductive metal oxide, a transparent conductive material, and the like. These may be used alone or in combination.

The pixel defining layer PDL may be disposed on the third planarization layer 230. In an embodiment, the pixel defining layer PDL may include the openings OP1, OP2, and OP3 each aligned with a portion of the pixel electrodes PE1, PE2, and PE3, respectively. The pixel defining layer PDL may include an organic material or an inorganic material. For example, the pixel defining layer PDL may include an organic material such as polyimide.

The light emitting layers EL1, EL2, and EL3 may be disposed on the pixel electrodes PE1, PE2, and PE3. Specifically, the light emitting layers EL1, EL2, and EL3 may be disposed in the openings OP1, OP2, and OP3 of the pixel defining layer PDL, respectively. The light emitting layers EL1, EL2, and EL3 may emit red light, green light, or blue light. For example, the first light emitting layer EL1 may emit red light, the second light emitting layer EL2 may emit green light, and the third light emitting layer EL3 may emit blue light. For example, the light emitting layers EL1, EL2, and EL3 may include a low molecular weight organic compound or a high molecular weight organic compound.

The common electrode CE may be disposed on the pixel defining layer PDL and the light emitting layers EL1, EL2, and EL3. For example, the common electrode CE may include a metal, an alloy, a metal nitride, a conductive metal oxide, a transparent conductive material, and the like. These may be used alone or in combination.

Accordingly, the light emitting elements 300a, 300b, and 300c including the pixel electrodes PE1, PE2, and PE3, the light emitting layers EL1, EL2, and EL3, and the common electrode CE may be disposed on the base substrate 100.

The encapsulation layer 240 may be disposed on the common electrode CE. The encapsulation layer 240 may prevent impurities, moisture, and the like from penetrating into the light emitting elements 300a, 300b, and 300c from the outside. The encapsulation layer 240 may include at least one inorganic encapsulation layer and at least one organic encapsulation layer. For example, the inorganic encapsulation layer may include silicon oxide, silicon nitride, silicon oxynitride, and the like. These may be used alone or in combination with each other. The organic encapsulation layer may include a cured polymer such as polyacrylate.

That is, the display device 1000 according to an embodiment of the present invention may include the base substrate 100, the first pixel PX1 emitting red light, and the third pixel PX3 adjacent in the first direction D1 and emitting blue light. The first pixel PX1 and the third pixel PX3 may include the transistors 200a and 200c, the conductive patterns 210a and 210c disposed on the transistors 200a and 200c, the light emitting elements 300a and 300c disposed on the conductive patterns 210a and 210c, and the connection lines CL1 and CL3 connecting the conductive patterns 210a and 210c and the light emitting elements 300a and 300c, respectively. Accordingly, the display device 1000 may implement a high resolution (e.g., a resolution of about 500 ppi or more). In addition, power consumption of the display device 1000 may be reduced.

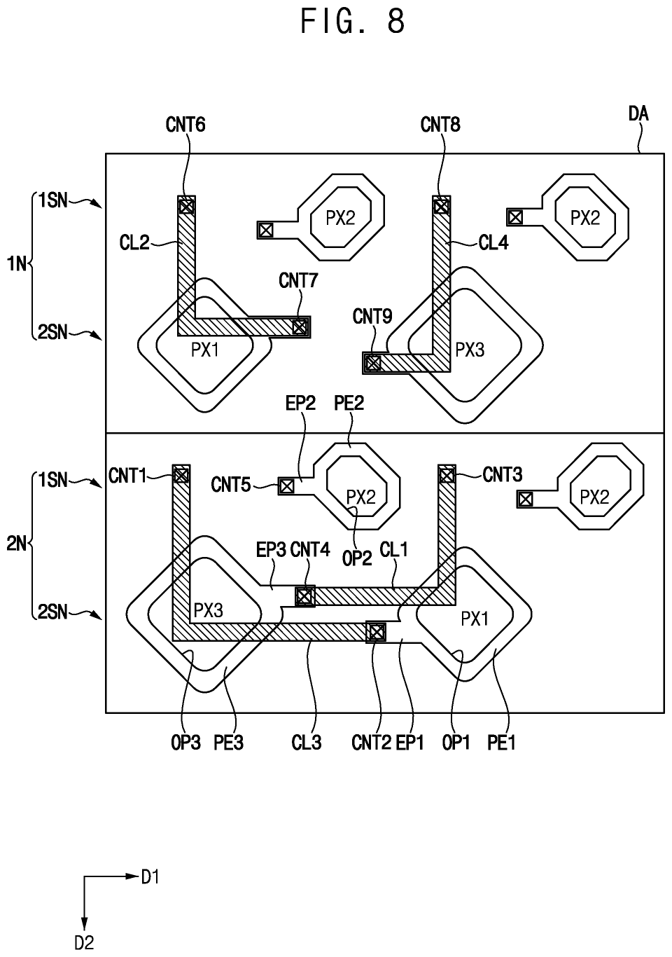

FIGS. 8, 9, and 10 are plan views illustrating an enlarged portion of a display area of a display device according to another embodiment.

Referring to FIGS. 8, 9 and 10, the display device according to another embodiment may include a plurality of pixels PX1, PX2, and PX3. However, in the display device described with reference to FIGS. 8, 9 and 10 may be substantially the same as or similar to the display device 1000 described with reference to FIGS. 2 and 3 except for a position of the extension portions EP1 and EP3 of the pixel electrodes PE1 and PE3 included in each of the pixels PX1 and PX3. Hereinafter, redundant descriptions will be omitted.

The first pixel electrode PE1 may include the first extension portion EP1, the second pixel electrode PE2 may include the second extension portion EP2, and the third pixel electrode PE3 may include the third extension portion EP3.

As illustrated in FIG. 8, the third extension potion EP3 located in the second sub-row 2SN of the first row 1N may be located farther along in the second direction D2 than the first extension portion EP1 located in the second sub-row 2SN of the first row 1N, in a plan view. In addition, the first extension portion EP1 located in the second sub-row 2SN of the second row 2N may be located farther along in the second direction D2 than the third extension portion EP3 located in the second sub-row 2SN of the second row 2N in a plan view.

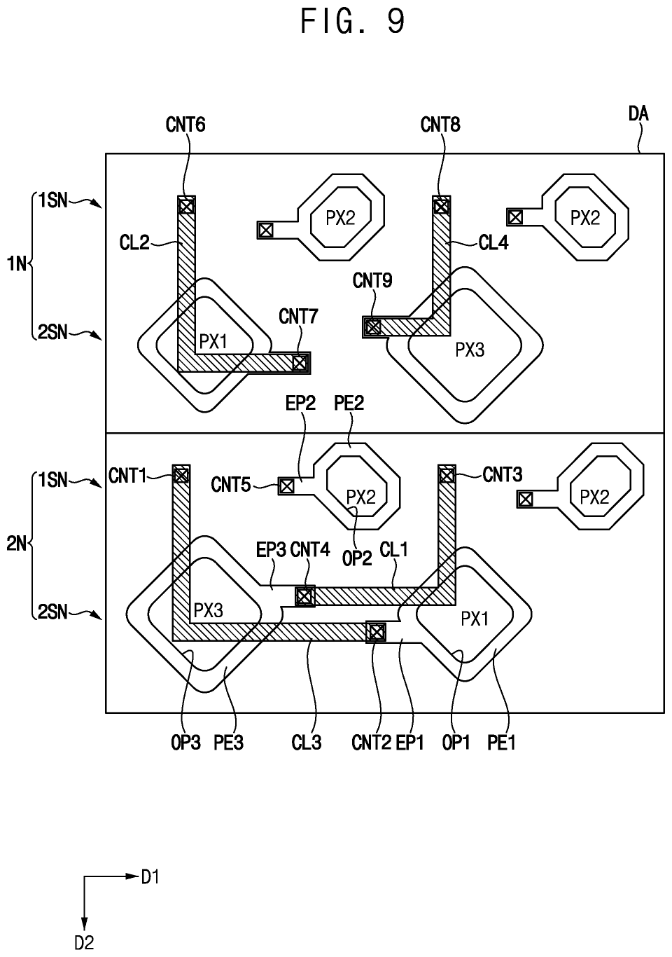

As illustrated in FIG. 9, the first extension potion EP1 located in the second sub-row 2SN of the first row 1N may be located farther along in the second direction D2 than the third extension portion EP3 located in the second sub-row 2SN of the first row 1N in a plan view. In addition, the first extension potion EP1 located in the second sub-row 2SN of the second row 2N may be located farther along in the second direction D2 than the third extension portion EP3 located in the second sub-row 2SN of the second row 2N in a plan view.

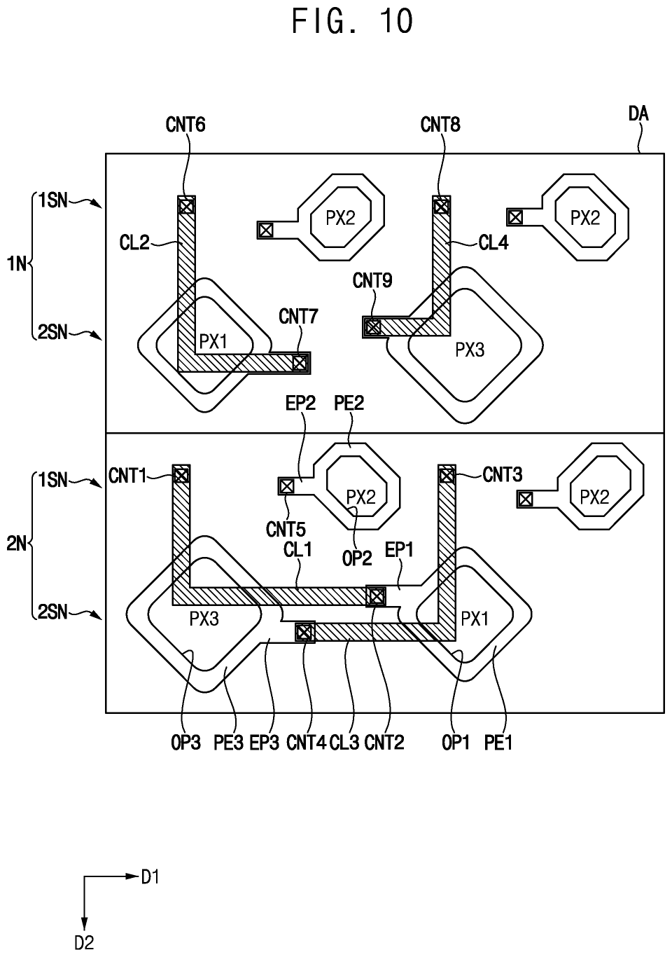

As illustrated in FIG. 10, the first extension potion EP1 located in the second sub-row 2SN of the first row 1N may be located farther along in the second direction D2 than the third extension portion EP3 located in the second sub-row 2SN of the first row 1N in a plan view. In addition, the third extension potion EP3 located in the second sub-row 2SN of the second row 2N may be located farther along in the second direction D2 than the first extension portion EP1 located in the second sub-row 2SN of the second row 2N in a plan view.

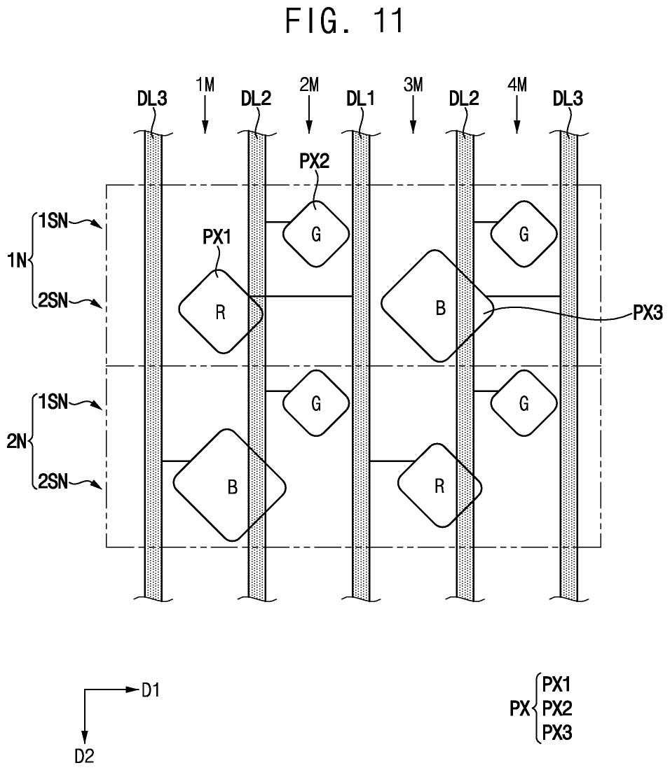

FIG. 11 is a plan view illustrating pixels and data lines of a display device according to still another embodiment.

Referring to FIG. 11, the display device may include the plurality of pixels PX. However, the display device described with reference to FIG. 11 may be substantially the same as or similar to the display device 1000 described with reference to FIG. 2 except for the number and connection method of the data lines DL. Hereinafter, overlapping descriptions will be omitted.

As described above, the data lines DL may include the first data lines DL1, the second data lines DL2, and the third data lines DL3.

For example, the first data line DL1 adjacent to the second column 2M may be connected the first pixel PX1 arranged in the second sub-row 2SN of the first row 1N and the first column 1M and the first data line DL1 may be connected the first pixel PX1 arranged in the in the second sub-row 2SN of the second row 2N and the third column 3M. In addition, the third data line DL3 adjacent to the first column 1M may be connected to the third pixel PX3 arranged in the second sub-row 2SN of the second row 2N and the first column 1M. In addition, the third data line DL3 adjacent to the fourth column 4M may be connected to the third pixel PX3 arranged in the second sub-row 2SN of the first row 1N and the third column 3M.

Accordingly, while the number of pixels PX is the same, the display device 1000 illustrated in FIG. 2 may include four data lines DL, and the display device illustrated in FIG. 11 may include five data lines DL. That is, the number of data lines DL of the display device illustrated in FIG. 11 may be greater than the number of data lines DL of the display device 1000 illustrated in FIG. 2 by one.

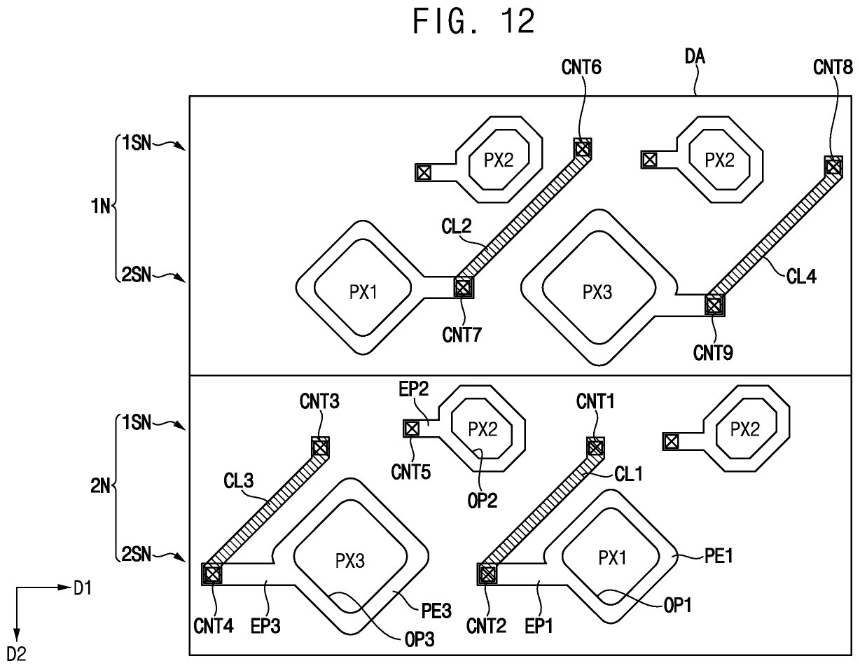

FIG. 12 is a plan view illustrating an enlarged portion of a display area of a display device according to still another embodiment. For example, FIG. 12 shows the pixel electrodes PE1, PE2, and PE3 of each of the pixels PX1, PX2, and PX3 of FIG. 11, the openings OP1, OP2, and OP3 of the pixel defining layer PDL, and the connection line CL1, CL2, CL3, and CL4.

Referring to FIGS. 11 and 12, the display device may include the plurality of pixels PX. However, the display device described with reference to FIG. 12 may be substantially the same as or similar to the display device 1000 described with reference to FIGS. 2 and 3 except for the shape and positions of the connection lines CL1, CL2, CL3, and CL4 included in each of the pixels PX1 and PX3. Hereinafter, any redundant descriptions will be omitted.

In an embodiment, each of the first, second, third, and fourth connection lines CL1, CL2, CL3, and CL4 may be spaced apart from the first opening OP1 and the third opening OP3 of the pixel defining layer (i.e., the pixel defining layer PDL of FIG. 4) in a plan view. That is, each of the first, second, third, and fourth connection lines CL1, CL2, CL3, and CL4 may not overlap the first opening OP1 and the third opening OP3 of the pixel defining layer PDL.

In an embodiment, the first, second, third, and fourth connection lines CL1, CL2, CL3, and CL4 may extend in the same direction. For example, the first, second, third, and fourth connection lines CL1, CL2, CL3, and CL4 may extend in a direction (e.g., a diagonal direction) crossing the first direction D1 and the second direction D2, respectively. That is, each of the first, second, third, and fourth connection lines CL1, CL2, CL3, and CL4 may extend in a specific direction so as not to overlap the first opening OP1 and the third opening OP3 of the pixel defining layer PDL.

The first pixel electrode PE1 may include the first extension portion EP1, the second pixel electrode PE2 may include the second extension portion EP2, and the third pixel electrode PE3 may include the third extension portion EP3.

In an embodiment, when the pixels PX1, PX2, and PX3 are arranged in the even-numbered row (e.g., the second row 2N), each of the first, second, and third extension portions EP1, EP2, and EP3 may extend in a direction opposite to the first direction D1 from a first side (e.g., the lefthand side with respect to FIG. 12) of the respective pixels, in a plan view. That is, the first, second, and third extension portions EP1, EP2, and EP3 may extend in the same direction (e.g., in a direction opposite to the first direction D1) in a plan view.

The pixels PX1, PX2, and PX3 in the odd-numbered rows (e.g., the first row 1N) may have the extension portions that are arranged differently from the pixels PX1, PX2, and PX3 in the even-numbered rows. In an embodiment, when the pixels PX1, PX2, and PX3 are arranged in the odd-numbered rows (e.g., the first row 1N), each of the first extension portion EP1 and the third extension portion EP3 may extend in a first direction D1 from a second side (e.g., the righthand side with reference to FIG. 12) of the first pixel PX1 and the third pixel PX3 in a plan view, and the second extension portion EP2 may extend in a direction opposite to the first direction D1 from a first side (e.g., the lefthand side with reference to FIG. 12) of the second pixels PX2 in a plan view. That is, the first extension portion EP1 and the third extension portion EP3 may extend in the same direction (e.g., the first direction D1) from the same side (e.g., the second side) of the respective pixel in a plan view.

In the first and third pixel electrodes PE1 and PE3 located in the even-numbered row (e.g., the second row 2N), the first electrodes PE1 may be connected to the first connection line CL1 through the second contact hole CNT2, and the third pixel electrode PE3 may be connected to the third connection line CL3 through the fourth contact hole CNT4. Similarly, in the first and third pixel electrodes PE1 and PE3 located in the odd-numbered row (e.g., the first row 1N), the first pixel electrode PE1 may be connected to the second connection line CL2 through the seventh contact hole CNT7, and the third pixel electrode PE3 may be connected to the fourth connection line CL4 through the ninth contact hole CNT9.

The present disclosure can be applied to various display devices. For example, the present disclosure can be applied to high-resolution smartphones, mobile phones, smart pads, smart watches, tablet PCs, in-vehicle navigation systems, televisions, computer monitors, notebook computers, and the like.

The foregoing is illustrative of embodiments and is not to be construed as limiting. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a base substrate;
a first pixel including: a first transistor disposed on the base substrate, a first conductive pattern disposed on the first transistor, a first light emitting element disposed on the first conductive pattern, and a first connection line connecting the first conductive pattern and the first light emitting element; and
a second pixel adjacent to the first pixel in a first direction and including: a second transistor disposed on the base substrate, a second conductive pattern disposed on the second transistor, a second light emitting element disposed on the second conductive pattern, and a second connection line connecting the second conductive pattern and the second light emitting element.

2. The display device of claim 1, wherein each of the first connection line and the second connection line includes a metal material.

3. The display device of claim 1, wherein the first light emitting element includes: a first pixel electrode, a first light emitting layer, and a first common electrode sequentially disposed on the base substrate, and
wherein the second light emitting element includes: a second pixel electrode, a second light emitting layer, and a second common electrode sequentially disposed on the base substrate.

4. The display device of claim 3, wherein the first pixel electrode includes a first extension portion extending in the first direction, and the second pixel electrode includes a second extension portion extending either in the first direction or in a direction opposite to the first direction.

5. The display device of claim 4, further comprising:
a planarization layer covering the first connection line and the second connection line,
wherein the first extension portion of the first pixel electrode is connected to the first connection line through a first contact hole formed by removing a portion of the planarization layer, and
wherein the second extension portion of the second pixel electrode is connected to the second connection line through a second contact hole formed by removing a portion of the planarization layer

6. The display device of claim 3, further comprising:
a pixel defining layer disposed on the base substrate and including a first opening aligned with a portion of the first pixel electrode and a second opening aligned with a portion of the second pixel electrode.

7. The display device of claim 6, wherein the first pixel and the second pixel are alternately arranged in an even-numbered row, and
the first connection line aligns with the second opening, and the second connection line aligns with the first opening.

8. The display device of claim 6, wherein the first pixel and the second pixel are alternately arranged in an odd-numbered row, and
the first connection line aligns with the first opening, and the second connection line aligns with the second opening.

9. The display device of claim 6, wherein the firs connection line is spaced apart from the first opening and the second opening in a plan view, and the second connection line is spaced apart from the first opening and the second opening in the plan view.

10. The display device of claim 1, wherein the first connection line has an “L” shape and the second connection line has an “L” shape rotated by 90 degrees relative to the first connection line, in a plan view.

11. The display device of claim 1, wherein the first connection line extends in a same direction as the second connection line.

12. The display device of claim 1, further comprising:
a third pixel adjacent to the first pixel and the second pixel in a second direction orthogonal to the first direction and including a third transistor, a third conductive pattern, and a third light emitting element sequentially disposed on the base substrate.

13. The display device of claim 12, wherein the third pixel is repeatedly arranged in each of a first sub-row of a first row and a first sub-row of a second row, and the first pixel and the second pixel are alternately arranged in each of a second sub-row of the first row and a second sub-row of the second row.

14. The display device of claim 12, wherein the first pixel is a red sub-pixel, the second pixel is a blue sub-pixel, and the third pixel is a green sub-pixel.

15. The display device of claim 12, further comprising:
a first data line connected to the first pixel and configured to provide a red data signal to the first pixel; and
a second data line connected to the second pixel and configured to provide a blue data signal to the second pixel.

16. A display device comprising:
a base substrate;
a transistor disposed on the base substrate;
a conductive pattern disposed on the transistor and connected to the transistor;
a light emitting element including a pixel electrode, a light emitting layer, and a common electrode sequentially disposed on the conductive pattern;
a pixel defining layer disposed on the conductive pattern and including an opening aligned with a portion of the pixel electrode; and
a connection line disposed between the conductive patten and the pixel electrode.

17. The display device of claim 16, wherein the connection line is aligned with the opening.

18. The display device of claim 16, wherein the connection line is spaced apart from the opening in a plan view.

19. The display device of claim 16, wherein the connection line has an “L” shape in a plan view.

20. The display device of claim 16, wherein the light emitting element emits red light or blue light.
